(19) United States
(12) Patent Application Publication
(10) Pub. No.: US 2022/0238432 A1
(43) Pub. Date: Jul. 28, 2022

(54) SEMICONDUCTOR DEVICE

(71) Applicant: Kioxia Corporation, Tokyo (JP)

(72) Inventor: Hiroshi MATSUMOTO, Yokkaichi (JP)

(73) Assignee: Kioxia Corporation, Tokyo (JP)

(21) Appl. No.: 17/391,527

(22) Filed: Aug. 2, 2021

(30) Foreign Application Priority Data
Jan. 27, 2021 (JP) 2021-011087

(51) Int. Cl. H01L 23/522; H01L 27/11582; H01L 27/11575

(52) U.S. Cl. CPC H01L 23/5226; H01L 27/11575; H01L 27/11582

(57) ABSTRACT

A semiconductor device includes a first insulating layer on a semiconductor substrate. A first conductive film is on the first insulating layer. A first stacked structure is on the first conductive film and includes first electrode films and second insulating layers alternately stacked. A conductive member is along an outer edge of the first stacked structure around the first stacked structure and electrically connected to the semiconductor substrate. A second stacked structure is provided at least partially around the conductive member and includes the second insulating layers and third insulating layers alternately stacked on the first conductive film. The first conductive film includes a body part below the first stacked structure, a periphery part provided at a periphery of the body part away from the body part, and a slit part in the first conductive film between the conductive member and the second stacked structure in the periphery part.

### CROSS REFERENCE TO RELATED APPLICATIONS

This application is based upon and claims the benefit of priority from the prior Japanese Patent Application No. 2021-011087, filed on Jan. 27, 2021, the entire contents of which are incorporated herein by reference.

### FIELD

The embodiments of the present invention relate to a semiconductor device.

### BACKGROUND

Semiconductor devices such as a NAND flash memory have a structure in which a memory cell array is provided above a CMOS (Complementary Metal Oxide Semiconductor) circuit in some cases for the purpose of downscaling. In such cases, source lines for the memory cell array are arranged between the memory cell array and the CMOS circuit.

However, there is a risk that film peeling at end portions of memory chips propagates to inner parts of the memory chips through between the source lines and the memory cell array in a dicing process.

### BRIEF DESCRIPTION OF THE DRAWINGS

FIG. 1A is a schematic perspective view illustrating an example of a semiconductor device according to a first embodiment;

FIG. 1B is a schematic plan view illustrating a stacked body;

FIGS. 2A and 2B are schematic sectional views illustrating an example of memory cells in a three-dimensional structure;

FIG. 3 is a schematic plan view illustrating an example of the semiconductor device according to the first embodiment;

FIG. 4 is a plan view illustrating a configuration example of the conductive layer and the semiconductor part;

FIG. 5 is a plan view illustrating a layout example of the conductive layer and the semiconductor part in a wafer manufacturing process;

FIG. 6 is an enlarged view illustrating a configuration example in a frame in FIG. 5;

FIG. 7 is an enlarged view illustrating a configuration example in a frame in FIG. 6;

FIG. 8 is a sectional view along a line 8-8 in FIG. 7;

FIG. 9A is a sectional view illustrating a configuration example of a semiconductor device according to a second embodiment;

FIG. 9B is a sectional view illustrating a configuration example of a semiconductor device according to a modification of the second embodiment;

FIG. 10A is a sectional view illustrating a configuration example of a semiconductor device according to a third embodiment;

FIG. 10B is a sectional view illustrating a configuration example of a semiconductor device according to a modification of the third embodiment;

FIG. 11 is a sectional view illustrating a configuration example of a semiconductor device according to a fourth embodiment; and

FIG. 12 is a sectional view illustrating a configuration example of a semiconductor device according to a fifth embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction perpendicular to a surface of a semiconductor substrate on which semiconductor elements are provided is assumed as “an upper direction”. Therefore, the term “upper direction” or “lower direction” occasionally differs from an upper direction or a lower direction based on a gravitational acceleration direction. In the present specification and the drawings, elements identical to those described in the foregoing drawings are denoted by like reference characters and detailed explanations thereof are omitted as appropriate.

A semiconductor device according to the present embodiment comprises a semiconductor substrate. A first insulating layer is provided on the semiconductor substrate. A first conductive film is provided on the first insulating layer. A first stacked structure is provided on the first conductive film and includes a plurality of first electrode films and a plurality of second insulating layers alternately stacked. A semiconductor member extends in the first stacked structure in a staking direction of the first electrode films. A charge accumulating member is provided between one of the first electrode films and the semiconductor member. A conductive member is provided along an outer edge of the first stacked structure around the first stacked structure and electrically connected to the semiconductor substrate. A second stacked structure is provided at least partially around the conductive member and includes the second insulating layers and a plurality of third insulating layers alternately stacked on the first conductive film. The first conductive film comprises a body part arranged below the first stacked structure, a periphery part provided at a periphery of the body part away from the body part, and a slit part provided in the first conductive film between the conductive member and the second stacked structure in the periphery part.

### First Embodiment

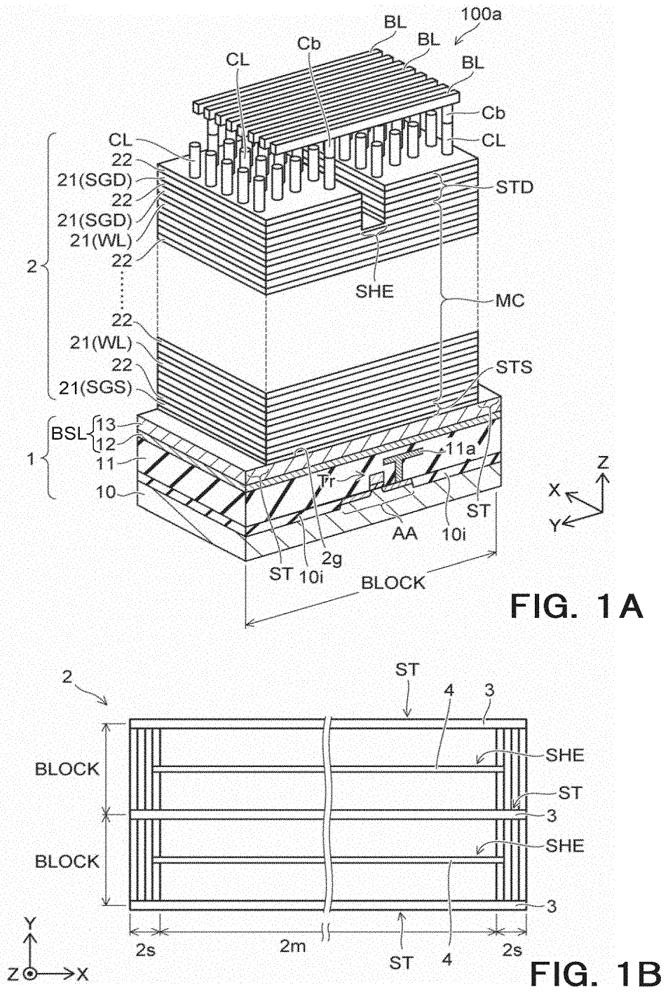

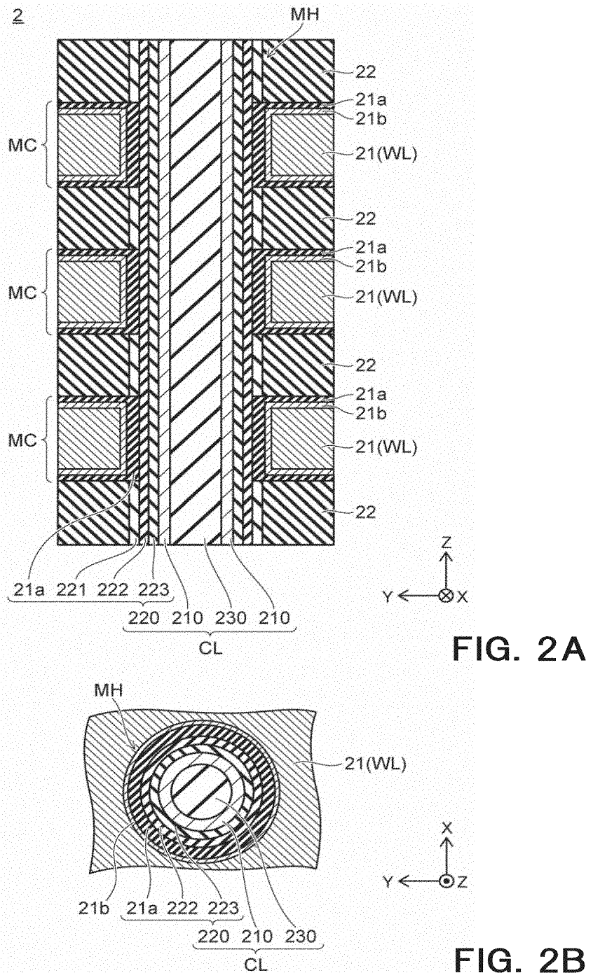

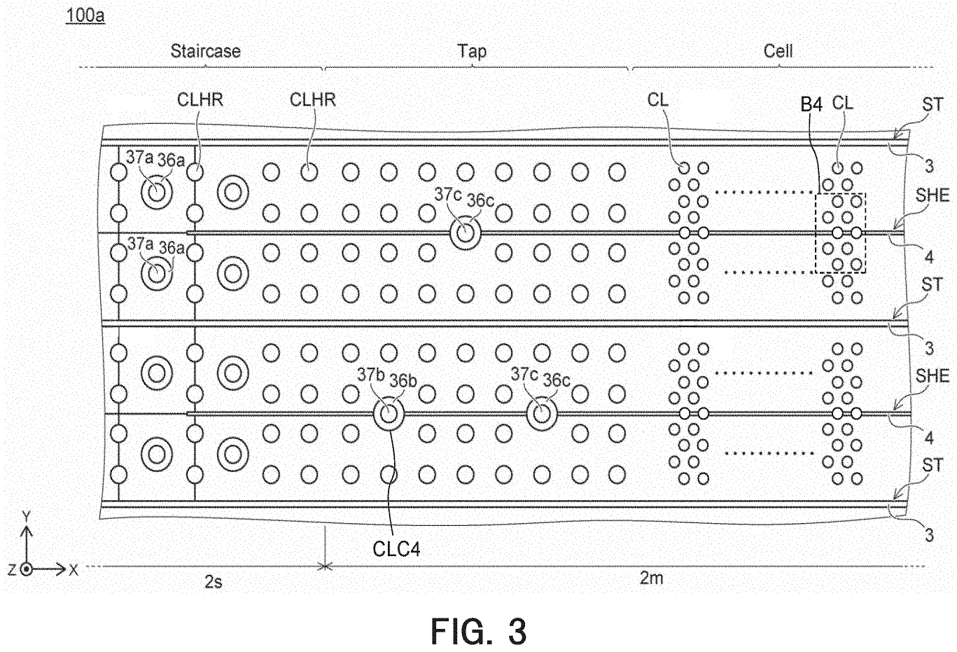

FIG. 1A is a schematic perspective view illustrating an example of a semiconductor device (for example, a semiconductor storage device 100a) according to a first embodiment. FIG. 1B is a schematic plan view illustrating a stacked body 2 in FIG. 1A. In the present specification, the stacking direction of the stacked body 2 is a Z direction. One direction intersecting with, for example, being orthogonal to the Z direction is a Y direction. One direction intersecting with, for example, being orthogonal to the Z and Y directions is an X direction. FIGS. 2A and 2B are schematic sectional views illustrating an example of memory cells in a three-dimensional structure. FIG. 3 is a schematic plan view illustrating an example of the semiconductor device according to the first embodiment.

As illustrated in FIGS. 1A to 3, the semiconductor storage device 100a according to the first embodiment is a non-volatile memory having memory cells in a three-dimensional structure.

The semiconductor storage device 100a includes a base part 1, the stacked body 2, deep slits ST (plate-like parts 3), shallow slits SHE (plate-like parts 4), and a plurality of columnar parts CL.

The base part 1 includes a substrate 10, an interlayer dielectric film 11, a conductive layer 12, and a semiconductor part 13. The interlayer dielectric film 11 being a first insulating layer is provided on the substrate 10. The conductive layer 12 is provided on the interlayer dielectric film 11. The semiconductor part 13 is provided on the conductive layer 12.

The substrate 10 is a semiconductor substrate, for example, a silicon substrate. The conductivity type of silicon (Si) is, for example, the p-type. For example, element isolation regions 10i are provided on a surface region of the substrate 10. The element isolation regions 10i are, for example, insulating regions including silicon oxide (SiO₂) and define active areas AA in the surface region of the substrate 10. Source and drain regions of transistors Tr are provided in the active areas AA. The transistors Tr constitute a peripheral circuit (a CMOS circuit) of the non-volatile memory. The CMOS circuit is provided below a buried source layer BSL and is provided on the substrate 10. The interlayer dielectric film 11 includes, for example, silicon oxide and insulates the transistors Tr. Lines 11a are provided in the interlayer dielectric film 11. Some of the lines 11a are electrically connected to the transistors Tr. The conductive layer 12 includes conductive metal, for example, tungsten (W). The semiconductor part 13 includes, for example, silicon. The conductivity type of silicon is, for example, the n-type. The semiconductor part 13 may include a plurality of layers and some of the layers may include undoped silicon. Either the conductive layer 12 or the semiconductor part 13 may be omitted.

The conductive layer 12 and the semiconductor part 13 function as a common source line for a memory cell array (2m in FIG. 1B). The conductive layer 12 and the semiconductor part 13 are electrically connected as one unit of a first conductive film and is also collectively referred to as “the buried source layer BSL”.

The stacked body 2 being a first stacked structure is provided above the semiconductor substrate 10 and is positioned in the Z direction with respect to the conductive layer 12 and the semiconductor part 13 (the buried source layer BSL). The stacked body 2 is configured by alternately stacking a plurality of electrode films 21 and a plurality of insulating layers (second insulating layers) 22 along the Z direction. The electrode films include conductive metal, for example, tungsten. The insulating layers 22 include, for example, silicon oxide. The insulting layers 22 insulate the electrode films 21 from each other. The number of the electrode films 21 and the insulating layers 22 can be any number. The insulating layers 22 may be, for example, air gaps. For example, an insulating film 2g is provided between the stacked body 2 and the semiconductor part 13. The insulating film 2g includes, for example, silicon oxide. The insulating film 2g may include a high-dielectric body having a higher relative dielectric constant than that of silicon oxide. The high-dielectric body may be, for example, a metal oxide.

The electrode films 21 include at least one source-side selection gate SGS, a plurality of word lines WL, and at least one drain-side selection gate SGD. The source-side selection gate SGS is gate electrodes of source-side selection transistors STS. The word lines WL are gate electrodes of memory cells MC. The drain-side selection gate SGD is gate electrodes of drain-side selection transistors STD. The source-side selection gate SGS is provided in a lower region of the stacked body 2. The drain-side selection gate SGD is provided in an upper region of the stacked body 2. The lower region indicates a region in the stacked body 2 on a side closer to the base part 1 and the upper region indicates a region in the stacked body 2 on a side far from the base part 1. The word lines WL are provided between the source-side selection gate SGS and the drain-side selection gate SGD.

The thickness in the Z direction of an insulating layer 22 that insulates the source-side selection gate SGS from the word lines WL among the insulating layers 22 can be, for example, larger than the thickness in the Z direction of each insulating layer 22 that insulates a word line WL and a word line WL from each other. A cover dielectric film (not illustrated) may be further provided on a topmost insulating layer 22 that is farthest from the base part 1. The cover dielectric film includes, for example, silicon oxide.

The semiconductor storage device 100a includes a plurality of memory cells MC connected in series between each of the source-side selection transistors STS and each of the drain-side selection transistors STD. A structure in which the source-side selection transistor STS, memory cells MC, and the drain-side selection transistor STD are connected in series is called “memory string” or “NAND string”. Each memory string is connected to, for example, a bit line BL via a contact Cb. Bit lines BL are provided above the stacked body 2 and extend in the Y direction.

The deep slits ST and the shallow slits SHE are provided in the stacked body 2. The deep slits ST extend in the X direction and are provided in the stacked body 2 while penetrating through the stacked body 2 from the top end of the stacked body 2 to the base part 1. The plate-like parts 3 are lines respectively provided in the deep slits ST (FIG. 1B). The plate-like parts 3 are made of a conductive film (a second conductive film) that is electrically insulated from the stacked body 2 by an insulating film (not illustrated) provided on inner walls of the deep slits ST and that is embedded in the deep slits ST to be electrically connected to the buried source layer BSL. The plate-like parts 3 are sometimes filled with, for example, an insulating material such as a silicon oxide film. Meanwhile, the shallow slits SHE extend in the X direction and are provided from the top end of the stacked body 2 to the middle of the stacked body 2. The shallow slits SHE penetrate through the upper region of the stacked body 2 where the drain-side selection gate SGD is provided. For example, the plate-like parts 4 are respectively provided in the shallow slits SHE (FIG. 1B). The plate-like parts 4 are, for example, silicon oxide.

As illustrated in FIG. 1B, the stacked body 2 includes staircase parts 2s and the memory cell array 2m. The staircase parts 2s are respectively provided at edge portions of the stacked body 2. The memory cell array 2m is sandwiched or enclosed by the staircase parts 2s. The deep slits ST are provided from the staircase part 2s at one end of the stacked body 2 to the staircase part 2s at the other end of the stacked body 2 through the memory cell array 2m. The shallow slits SHE are provided at least in the memory cell array 2m.

As illustrated in FIG. 3, the memory cell array 2m includes cell regions (Cell) and tap regions (Tap). The staircase parts 2s include staircase regions (Staircase). The tap regions are provided, for example, between a cell region and a staircase region. Although not illustrated in FIG. 3, the tap regions may be provided between cell regions. The staircase regions are regions where a plurality of lines 37a are provided. The tap regions are regions where lines 37b and 37c are provided. The lines 37a to 37c extend, for example, in the Z direction. The lines 37a are, for example, electrically connected to the electrode films 21, respectively. The lines 37b are, for example, electrically connected to the conductive layer 12. The lines 37c are, for example, electrically connected to the lines 11a.

A portion of the stacked body 2 sandwiched between two plate-like parts 3 illustrated in FIG. 1B is called “block (BLOCK)”. The block is, for example, a smallest unit of data erase. The plate-like parts 4 are provided in the blocks, respectively. A portion of the stacked body 2 between one of the plate-like parts 3 and one of the plate-like parts 4 is called “finger”. The drain-side selection gate SGD is divided for each finger. Therefore, one finger in one block can be brought to a selected state by the drain-side selection gate SGD at the time of data write and read.

As illustrated in FIG. 2A, each of the columnar parts CL is provided in a memory hole MH formed in the stacked body 2. Each of the columnar parts CL penetrates along the Z direction through the stacked body 2 from the top end of the stacked body 2 and is provided in the stacked body 2 and the buried source layer BSL. Each of the columnar parts CL includes a semiconductor body 210, a memory film 220, and a core layer 230. The columnar parts CL each include the core layer 230 provided at the center, the semiconductor body 210 provided around the core layer 230, and the memory film 220 provided around the semiconductor body 210. The semiconductor body 210 is electrically connected to the buried source layer BSL. The memory film 220 serving as a charge accumulating member has charge trapping portions between the semiconductor body 210 and the electrode films 21. A plurality of columnar parts CL each selected from each finger are connected in common to one bit line BL via contacts Cb. The columnar parts CL are provided, for example, in the cell regions (Cell) (FIG. 3).

As illustrated in FIG. 2B, the shape of the memory hole MH in an X-Y plane is, for example, a circle or an ellipse. A block dielectric film 21a constituting a portion of the memory film 220 may be provided between the electrode films 21 and the insulating layers 22. The block dielectric film 21a is, for example, a silicon oxide film or a metal oxide film. One example of the metal oxide is aluminum oxide. A barrier film 21b may be provided between the electrode films 21 and the insulating layers 22 and between the electrode films 21 and the memory film 220. For example, titanium nitride is selected as the barrier film 21b when the electrode films 21 are tungsten. The block dielectric film 21a suppresses back tunnelling of charges from the electrode films 21 toward the memory film 220. The barrier film 21b improves adhesion between the electrode films 21 and the block dielectric film 21a.

The shape of the semiconductor body 210 being a semiconductor member is, for example, a tube having a bottom. The semiconductor body 210 includes, for example, silicon. Silicon is, for example, polycrystalline silicon including crystallized amorphous silicon. The semiconductor body 210 is, for example, undoped silicon. The semiconductor body 210 may be p-type silicon. The semiconductor body 210 functions as a channel of each of the drain-side selection transistor STD, the memory cells MC, and the source-side selection transistor STS.

A portion of the memory film 220 other than the block dielectric film 21a is provided between the inner wall of the associated memory hole MH and the semiconductor body 210. The shape of the memory film 220 is, for example, tubular. The memory cells MC have storage regions between the semiconductor body 210 and the electrode films 21 functioning as the word lines WL and are stacked in the Z direction. The memory film 220 includes, for example, a cover dielectric film 221, a charge trapping film 222, and a tunnel dielectric film 223. The semiconductor body 210, the charge trapping film 222, and the tunnel dielectric film 223 extend in the Z direction.

The cover dielectric film 221 is provided between the insulating layers 22 and the charge trapping film 222. The cover dielectric film 221 includes, for example, silicon oxide. The cover dielectric film 221 protects the charge trapping film 222 so as not to be etched when sacrificial films (not illustrated) are respectively replaced with the electrode films 21 (a replacing process). The cover dielectric film 221 may be removed from between the electrode films 21 and the memory film 220 in the replacing process. In this case, for example, the block dielectric film 21a is provided between the electrode films 21 and the charge trapping film 222 as illustrated in FIGS. 2A and 2B. The cover dielectric film 221 may be omitted when the replacing process is not used to form the electrode films 21.

The charge trapping film 222 is provided between the block dielectric film 21a and the cover dielectric film 221, and the tunnel dielectric film 223. The charge trapping film 222 includes, for example, silicon nitride and has a trapping site that traps charges in the film. Portions of the charge trapping film 222 sandwiched between the electrode films 21 functioning as the word lines WL and the semiconductor body 210 respectively constitute the storage regions of the memory cells MC as charge trapping portions. A threshold voltage of each of the memory cells MC changes according to whether there are charges in the associated charge trapping portion or the amount of charges trapped in the charge trapping portion. Each of the memory cells MC accordingly retains information.

The tunnel dielectric film 223 is provided between the semiconductor body 210 and the charge trapping film 222. The tunnel dielectric film 223 includes, for example, silicon oxide, or silicon oxide and silicon nitride. The tunnel dielectric film 223 is a potential barrier between the semiconductor body 210 and the charge trapping film 222. For example, when electrons are injected from the semiconductor body 210 to a charge trapping portion (a write operation) and when positive holes are injected from the semiconductor body 210 to a charge trapping portion (an erase operation), the electrons and the positive holes pass (tunnel) through the potential barrier of the tunnel dielectric film 223.

The core layer 230 fills an internal space of the tubular semiconductor body 210. The shape of the core layer 230 is, for example, columnar. The core layer 230 includes, for example, silicon oxide and is insulative.

Each of a plurality of columnar parts CLHR in FIG. 3 is provided in a hole formed in the stacked body 2. The holes penetrate through the stacked body 2 from the top end of the stacked body 2 along the Z direction to be provided in the stacked body 2 and the semiconductor part 13. Each of the columnar parts CLHR includes at least an insulator. The insulator is, for example, silicon oxide. Each of the columnar parts CLHR may have a same structure as that of the columnar parts CL. The columnar parts CLHR are provided, for example, in the staircase regions (Staircase) and the tap regions (Tap). The columnar parts CLHR function as support members for holding voids formed in the staircase regions and the tap regions when sacrificial films (not illustrated) are respectively replaced with the electrode films 21 (the replacing process). A plurality of columnar parts CLC4 are also provided in the tap regions (Tap) of the stacked body 2. Each of the columnar parts CLC4 includes the line 37b or 37c. The lines 37b are electrically insulated from the stacked body 2 by an insulator 36b. The lines 37b are electrically connected to the buried source line BSL. The lines 37c are electrically insulated from the stacked body 2 by an insulator 36c. The lines 37c are electrically connected to any of the lines 11a. The staircase regions (Staircase) further include the lines 37a functioning as contacts for the electrode films 21 in the stacked body 2, and insulators 36a respectively provided around the lines 37a.

The columnar parts CL, that is, the memory holes MH are arranged in a hexagonal close-packed array between two of the deep slits ST adjacent in the Y direction in a planar layout. The shallow slits SHE are provided so as to overlap with some of the columnar parts CL as illustrated in a frame B4 in FIG. 3. No memory cells are formed on the columnar parts CL formed below the shallow slits SHE.

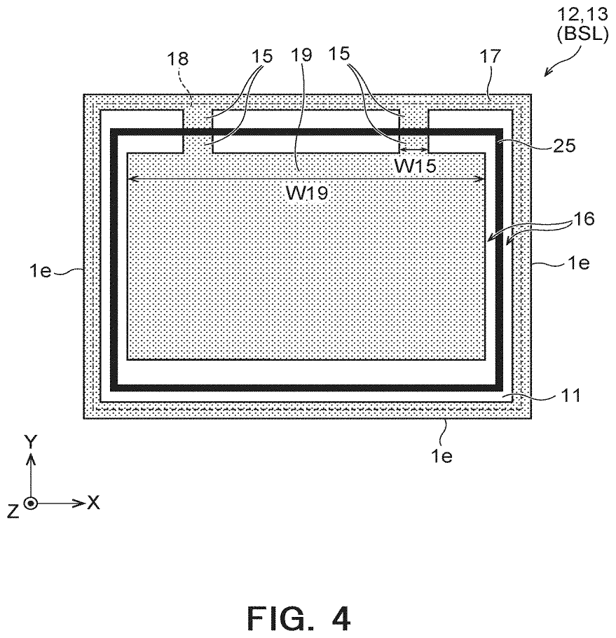

FIG. 4 is a plan view illustrating a configuration example of the conductive layer 12 and the semiconductor part 13 (the buried source layer BSL). FIG. 4 illustrates a plane of the buried source layer BSL corresponding to the whole of one chip of the semiconductor storage device 100a.

The buried source layer BSL being a first conductive film includes a body part 19, protruding parts 15, and a periphery part 17. The body part 19, the protruding parts 15, and the periphery part 17 are made of a same material and in a same layer. In the buried source layer BSL, particularly the body part 19 is electrically connected to the semiconductor body 210 illustrated in FIGS. 2A and 2B and functions as sources of the memory cell array 2m.

The body part 19 is provided below the electrode films 21 constituting the memory cell array 2m. That is, the body part 19 is provided immediately above the transistors Tr constituting the CMOS circuit in FIG. 1A and immediately below the memory cell array 2m in FIG. 1B. The body part 19 has a substantially rectangular shape as viewed from the stacking direction (the Z direction) of the stacked body 2 as illustrated in FIG. 4. In the present specification, the “substantially rectangular shape” includes also shapes similar to a rectangular shape, such as a quadrangular shape having one or more curved sides, as well as the rectangular shape.

The periphery part 17 is provided at a periphery of the body part 19 and is away from the body part 19. The periphery part 17 is provided on dicing lines and an end portion 1e thereof is an outer edge of the chip of the semiconductor storage device 100a. Therefore, the substrate 10 and the like are cut by dicing at the end portion 1e. A space part 16 is provided between the periphery part 17 and the body part 19.

The protruding parts 15 are provided partially in the space part 16 between the body part 19 and the periphery part 17 and function as connecting parts that partially connect the body part 19 and the periphery part 17 to each other in the manufacturing process. The protruding parts 15 are separated by an insulating member 25 in a completed product as illustrated in FIG. 4 and extend in the Y direction from the body part 19 toward the periphery part 17 or from the periphery part 17 toward the body part 19. A width W15 of each of the protruding parts 15 in the X direction is narrower than a width W19 of the body part 19. That is, while the body part 19 and the periphery part 17 are partially connected via the protruding parts 15 to be configured electrically as one unit in the manufacturing process, the body part 19 and the periphery part 17 are separated by the insulating member 25 after completion. Therefore, since not separated in the manufacturing process, the protruding parts 15 are hereinafter also referred to as “connecting parts 15”. The number of the protruding parts 15 is not particularly limited to any specific number. The insulating member 25 may be a seal ring that is provided so as to encompass the body part 19.

In a completed product after formation of the buried source layer BSL, portions of the protruding parts (connecting parts) 15 of the buried source layer BSL are removed and the insulating member 25 is embedded therein as illustrated in FIG. 4. Accordingly, the body part 19 and the periphery part 17 are electrically isolated from each other by the insulating member 25. The plate-like parts 3 configured by embedding a conductive film in the deep slits ST are provided in the body part 19 of the buried source layer BSL (FIG. 1B) to obtain a configuration that enables a source voltage to be supplied to the buried source layer BSL via the conductive film in the deep slits ST.

After formation of the columnar parts CL (the memory holes MH) or the plate-like parts 3 (the deep slits ST), the protruding parts (the connecting parts) 15 are cut due to formation of the insulating member 25. In the completed product, the protruding parts 15 connected to the body part 19 are protruded in the Y direction from the body part 19 toward the periphery part 17 as illustrated in FIG. 4. The protruding parts 15 connected to the periphery part 17 are protruded in the Y direction from the periphery part 17 toward the body part 19. The protruding parts 15 of the body part 19 and the protruding parts 15 of the periphery part 17 are respectively provided at positions facing each other. Due to cutting of the protruding parts 15, the capacity of the buried source layer BSL can be reduced and the source voltage can be controlled at a high speed.

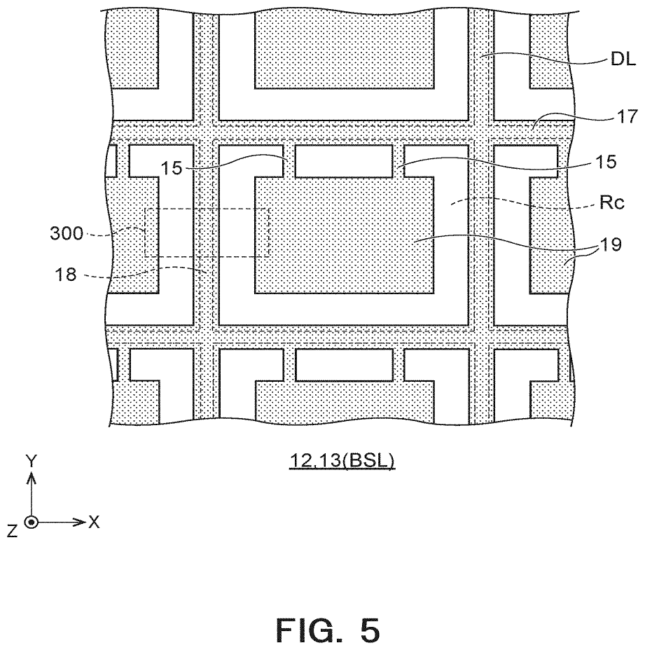

FIG. 5 is a plan view illustrating a layout example of the conductive layer 12 and the semiconductor part 13 (the buried source layer BSL) in a wafer manufacturing process. In the manufacturing process, the protruding parts (the connecting parts) 15 electrically connect the body part 19 and the periphery part 17 to each other and release charges accumulated in the body part 19 to the substrate 10 and the like via the periphery part 17 at the time of formation of the columnar parts CL (the memory holes MH) or the plate-like parts 3 (the deep slits ST). Accordingly, arcing between the body part 19 and the lines 11a and the like positioned thereunder can be suppressed. In FIG. 5, semiconductor chips are still connected at dicing lines DL.

Slit parts 18 are provided in the periphery part 17 so as to extend along outer edges of the semiconductor chips. The slit parts 18 may be provided entirely at the peripheries of the semiconductor chips or may be partially omitted. Chip body regions Rc surrounded by the periphery part 17 are regions that will become semiconductor chip bodies after dicing.

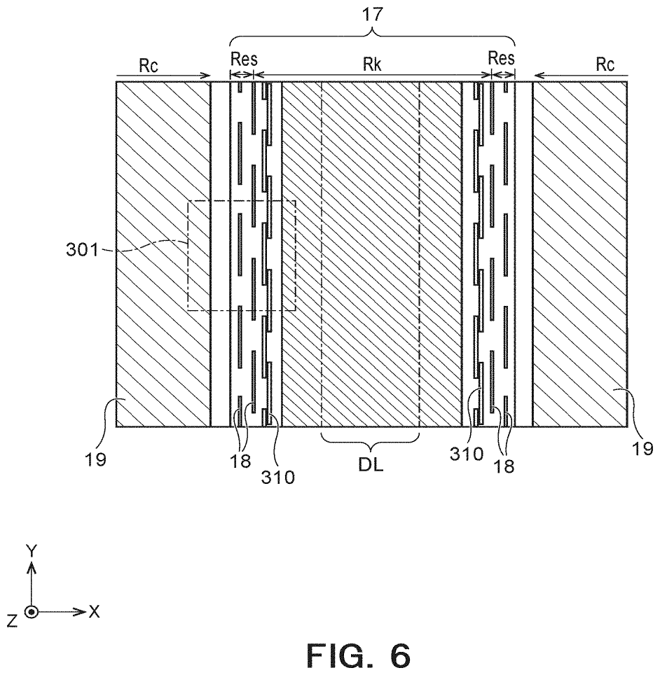

FIG. 6 is an enlarged view illustrating a configuration example in a frame 300 in FIG. 5. The periphery part 17 between two chip body regions Rc includes a kerf region Rk and edge seal regions Res. The dicing line DL is a region cut by a laser or a blade in the dicing process.

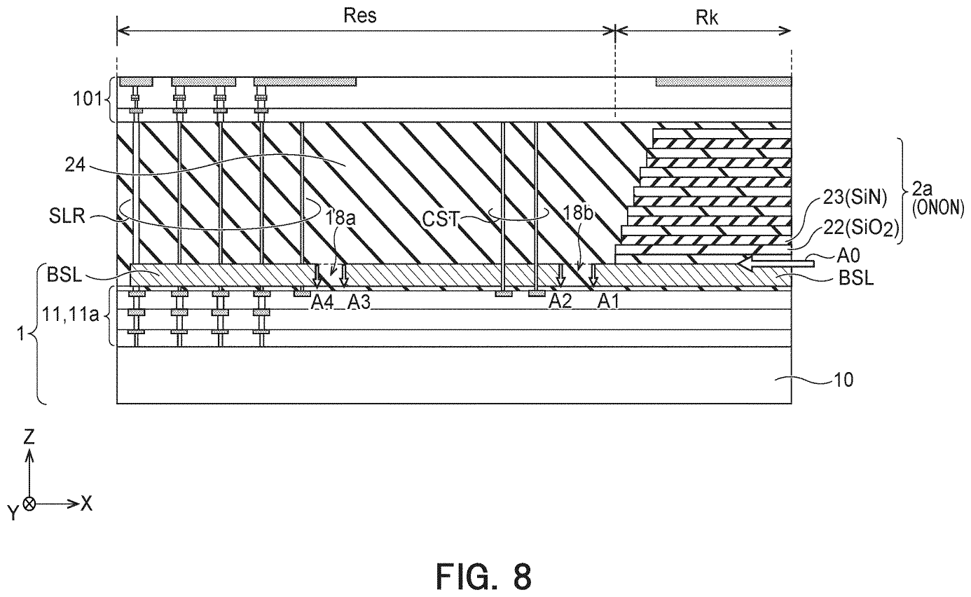

The kerf region Rk includes slit parts 310. The edge seal regions Res include slit parts 18. The slit parts 18 and 310 are provided in the periphery part 17 so as to extend along the outer edge of the body part 19. It is preferable that the slit parts 18 and 310 be provided to correspond to at least a stacked body 2a shown in FIG. 8 at the periphery of the body part 19 to suppress film peeling. However, the slit parts 18 and 310 may be provided entirely at the periphery of the body part 19. In the first embodiment, inner portions of the slit parts 18 and 310 are filled with an insulating film (for example, a silicon oxide film).

The end portion 1e of the semiconductor storage device 100a illustrated in FIG. 4 is included in the dicing line DL in FIG. 6 and is sometimes subjected to damages due to impact at the time of being cut by dicing. For example, the buried source layer BSL in FIG. 1 has a risk of peeling from the interlayer dielectric film 11 positioned thereunder or peeling from an interlayer dielectric film 24 or the stacked body 2a in FIG. 8 positioned thereon due to impact caused by the dicing. Damages such as the film peeling cause no problem when the damages remain only on the outermost edge of the periphery part 17 in FIG. 6.

However, if the slit parts 18 and 310 are not provided, there is a risk that such film peeling propagates from the periphery part 17 to the body part 19. Film peeling at the body part 19 reduces reliability of the semiconductor storage device 100a.

In order to solve this problem, the semiconductor device according to the present embodiment has the slit parts 18 and 310 provided at the periphery part 17 so as to extend at least along one portion of the outer edge of the body part 19. Accordingly, the film peeling described above stops at the slit parts 310 or the slit parts 18 and propagation of film peeling from the periphery part 17 to the body part 19 can be suppressed. The slit parts 18 and 310 are provided entirely in the thickness direction (the Z direction) of the periphery part 17. Therefore, both film peeling between the buried source layer BSL and the interlayer dielectric film 11 positioned thereunder and film peeing between the buried source layer BSL and the interlayer dielectric film 24 or the stacked body 2a positioned thereon can be suppressed.

On the other hand, if the slit parts 18 and 310 electrically disconnect an inside portion of the periphery part 17 and an outside portion thereof from each other, the outside portion of the periphery part 17 cannot be electrically connected to the body part 19 via the protruding parts (the connecting parts) 15 at the time of formation of the memory holes MH and the deep slits ST. In this case, the protruding parts (the connecting parts) 15 cannot release charges accumulated in the body part 19 to the substrate 10 and the like (the ground) via the outside portion of the periphery part 17.

In contrast thereto, according to the present embodiment, the slit parts 18 and 310 are respectively arranged alternately in a staggered manner as viewed from the Z direction or the X direction. Therefore, the inside portion of the periphery part 17 can be electrically connected to the outside portion thereof, and the outside portion of the periphery part 17 can be electrically connected to the body part 19 via the protruding parts (the connecting parts) 15.

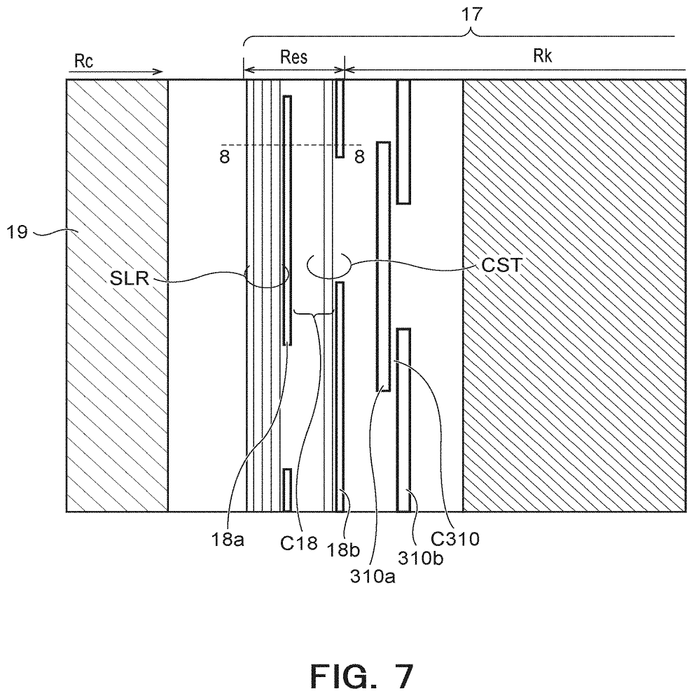

FIG. 7 is an enlarged view illustrating a configuration example in a frame 301 in FIG. 6. The slit parts 18 include slit parts 18a and slit parts 18b. As viewed from the stacking direction (the Z direction) of the stacked body 2, the slit parts 18a and 18b are arranged alternately in a staggered manner. As viewed from the Z direction, the slit parts 18a and 18b are not connected to each other and are separated from each other. Therefore, a connecting part C18 is provided between the slit parts 18a and the slit parts 18b. The connecting part C18 is a portion of the conductive film of the buried source layer BSL that electrically connects the inside portion of the periphery part 17 and the outside portion thereof to each other in the edge seal regions Res. The inside portion of the periphery part 17 is the buried source layer BSL on a side closer to the body part 19 than the slit parts 18a and 18b. The outside portion of the periphery part 17 is the buried source layer BSL on a side closer to the kerf region Rk than the slit parts 18a and 18b. Accordingly, at the time of forming the memory holes MH and the deep slits ST, charges accumulated in the body part 19 flow to the outside portion of the periphery part 17 via the protruding parts (the connecting parts) 15 and the connecting part C18 to be emitted to the substrate 10 and the like.

As viewed from a first direction (the X direction) from the body part 19 toward the periphery part 17, end portions of the slit parts 18a and 18b overlap with each other. Therefore, there is no gap between the slit parts 18a and the slit parts 18b as viewed from the X direction. Accordingly, the slit parts 18a and 18b can more reliably suppress progression of film peeling.

The slit parts 310 include slit parts 310a and slit parts 310b. As viewed from the Z direction, the slit parts 310a and 310b are arranged alternately in a staggered manner. As viewed from the Z direction, the slit parts 310a and the slit parts 310b are not connected to each other and are separated from each other. Therefore, a connecting part C310 is provided between the slit parts 310a and the slit parts 310b. The connecting part C310 is a portion of the conductive film of the buried source layer BLS that electrically connects the inside portion of the periphery part 17 and the outside portion thereof to each other in the kerf region Rk. Accordingly, at the time of forming the memory holes MH and the deep slits ST, charges accumulated in the body part 19 flow to the outside portion of the periphery part 17 via the protruding parts (the connection parts) 15 and the connecting part C310 to be emitted to the substrate 10 and the like. The protruding parts (the connecting parts) 15 are cut by formation of the insulating member 25 after the memory choles MH and the deep slits ST are formed.

As viewed from the X direction, end portions of the slit parts 310a and 310b overlap with each other. Therefore, there is no gap between the slit parts 310a and the slit parts 310b as viewed from the X direction. Accordingly, the slit parts 310a and 310b can more reliably suppress progression of film peeling.

As described above, according to the present embodiment, the slit parts 18 and 310 can suppress film peeling from the end portion 1e in FIG. 4 from propagating from the periphery part 17 to the body part 19 while keeping the electrical connection between the peripheral part 17 and the body part 19.

FIG. 8 is a sectional view along a line 8-8 in FIG. 7. In FIG. 8, the configuration of the edge seal region Res and the kerf region Rk is illustrated in more detail. In the edge seal region Res, a plurality of layers of the lines 11a are provided on the surface of the substrate 10 and the layers of the lines 11a are isolated from the surrounding region by the interlayer dielectric film 11. The layers of the lines 11a are preferably connected with ring-shaped contact plugs as viewed from the Z direction and are electrically connected to the buried source layer BSL and a seal ring body SLR provided thereon. The substrate 10, the interlayer dielectric film 11, the lines 11a, and the buried source layer BSL constitute the base part 1.

A multi-layer wiring layer 101 is provided on the seal ring body SLR. The multi-layer wiring layer 101 is electrically connected to the seal ring body SLR. The multi-layer wiring layer 101 can be formed to correspond to the bit lines BL and a wiring layer upper than the bit lines BL.

The seal ring body SLR being a conductive member cooperates with the layers of the lines 11a to function as a seal ring (an edge seal). This seal ring is provided in the thickness direction (the Z direction) of the chip between the substrate 10 and the multi-layer wiring layer 101 and is electrically connected to the substrate 10. It is preferable that the seal ring body SLR be continuously provided entirely along the outer edge of the stacked body 2 on the body part 19 as well as the layers of the lines 11a in a planar layout. A low-resistance metal such as copper is used as the seal ring body SLR and the layers of the lines 11a. Accordingly, the seal ring including the seal ring body SLR can release charges to the substrate 10 in order to suppress the memory cell array 2m, the CMOS circuit, and the like in the semiconductor chip from being broken by ESD (Electro-Static Discharge). Further, the seal ring including the seal ring body SLR can suppress hydrogen from entering from the end portion 1e to suppress degradation of the semiconductor chip due to the hydrogen after dicing of the semiconductor chip.

The slit parts 18a and 18b are provided in the buried source layer BSL on the side closer to the kerf region Rk than the seal ring body SLR. The slit parts 18a and 18b are openings provided in the buried source layer BSL between the seal ring body SLR and the stacked body 2a and are filled with a material of the interlayer dielectric film 24.

A crack stopper CST is provided between the slit parts 18a and the slit parts 18b. The crack stopper CST is provided in the thickness direction (the Z direction) of the chip between the base part 1 and the multi-layer wiring layer 101. It is preferable that the crack stopper CST be continuously provided entirely along the outer edge of the stacked body 2 on the body part 19. A low-resistance metal such as copper is used as the crack stopper CST. The crack stopper CST is provided to stop film peeling from progressing from the end portion 1e of the chip toward the kerf region Rk, the edge seal region Res, and the chip body region Rc. The crack stopper CST also has a function to suppress hydrogen from entering from the end portion 1e. The crack stopper CST may be used to suppress breaking of an inner part of the chip due to ESD.

The stacked body (an ONON structure) 2a in which insulating layers (silicon oxide films) 22 being second insulating layers and sacrificial films (silicon nitride films) 23 being third insulating layers are stacked is provided in the kerf region Rk as a second stacked structure on the buried source layer BSL. The stacked body 2a is provided along the outer edge of the stacked body 2 on the body part 19 at least partially around the seal ring body SLR. That is, the stacked body 2a is provided immediately above at least a portion of the periphery part 17 of the buried source layer BSL. For example, the stacked body 2a is provided only on a portion of the periphery part 17 facing a certain side of the periphery of the body part 19 in some cases. The stacked body 2a is sometimes provided discontinuously in the manner of islands on the periphery part 17. Alternatively, the stacked body 2a may be continuously provided on the periphery part 17 entirely therearound. Portions of the stacked body 2a are sometimes missing due to dicing. When the stacked body 2a including the insulating layers 22 and the sacrificial films 23 is provided on the buried source layer BSL, film peeling is likely to occur between the stacked body 2a and the buried source line BSL or the like as indicated by an arrow A0 in FIG. 8. The stacked body 2a may have a stacked structure including the insulating layers 22 and the electrode films 21, for example, in at least a portion on the side of the edge seal region Res. Also in this case, film peeling is likely to occur between the stacked body 2a and the buried source layer BSL or the like. The electrode films (for example, tungsten) 21 are harder to cut by a dicing blade than the sacrificial films (for example, silicon nitride films) 23. Therefore, if the stacked body 2a in the kerf region Rk has a stacked structure (an OWOW structure) in which the insulating layers 22 and the electrode films 21 are alternately stacked particularly on an outer edge side of the chip, the kerf region Rk is hard to cut by a dicing blade. In contrast thereto, according to the present embodiment, the kerf region Rk is easily cut by a dicing blade because the stacked body 2a in the kerf region Rk has the ONON structure.

When film peeling between the buried source layer BSL and the stacked body 2a progresses from the kerf region Rk, the slit parts 310a and 310b in FIG. 7 first suppress the film peeling. The slit parts 18b in the edge seal region Res subsequently suppress the film peeling. When the film peeling reaches the slit parts 18b, the film peeling can be guided in a −Z direction along one of interfaces between the interlayer dielectric film 24 in the slit parts 18b and the buried source layer BSL as indicated by an arrow A1 in FIG. 8. The film peeling can also be guided to the −Z direction along the other interface between the interlayer dielectric film 24 in the slit parts 18b and the buried source layer BSL as indicated by an arrow A2.

If the film peeling further progresses in a −X direction, the crack stopper CST and the slit parts 18a suppress the film peeling. When the film peeling reaches the slit parts 18a, the film peeling is guided in the −Z direction along one of interfaces between the interlayer dielectric film 24 in the slit parts 18a and the buried source layer BSL as indicated by an arrow A3. The film peeling can be guided to the −Z direction along the other interface between the interlayer dielectric film 24 in the slit parts 18a and the buried source layer BSL as indicated by an arrow A4.

In this way, according to the present embodiment, even when film peeling occurs in the ±X directions between the stacked body 2a and the buried source layer BLS, the film peeling can be guided to the direction (the −Z direction) indicated by the arrows A1 to A4 due to the slit parts 18a and 18b provided in the edge seal region Rea to suppress progression of the film peeling toward the chip body region Rc.

Since film peeling is likely to occur particularly between the stacked body 2a and the buried source layer BSL, it suffices to provide the slit parts 18a, 18b, 310a, and 310b to correspond to at least the stacked body 2a. That is, the slit parts 18a, 18b, 310a, and 310b in the edge seal region Res or the kerf region Rk are provided at the outer edge of the stacked body 2 on the body part 19 in such a pattern that overlaps with at least the stacked body 2a as viewed from the body part 19. For example, when the stacked body 2a is provided only on a portion of the periphery part 17 facing a certain side of the periphery of the body part 19, it suffices to provide the slit parts 18a, 18b, 310a, and 310b in the portion of the periphery part 17 facing this side. When the stacked body 2a is provided discontinuously in the manner of islands on the periphery part 17, it suffices to similarly provide the slit parts 18a, 18b, 310a, and 310b discontinuously in the manner of islands in the periphery part 17. When the stacked body 2a is provided continuously on the periphery part 17 entirely therearound, it is preferable that the slit parts 18a, 18b, 310a, and 310b be also continuously provided entirely around the periphery part 17.

The slit parts 18a, 18b, 310a, and 310b can be easily formed when a processing pattern for the buried source layer BSL (the conductive layer 12 and the semiconductor part 13) is changed. Therefore, detailed explanations of the manufacturing method of the semiconductor device according to the present embodiment are omitted.

### Second Embodiment

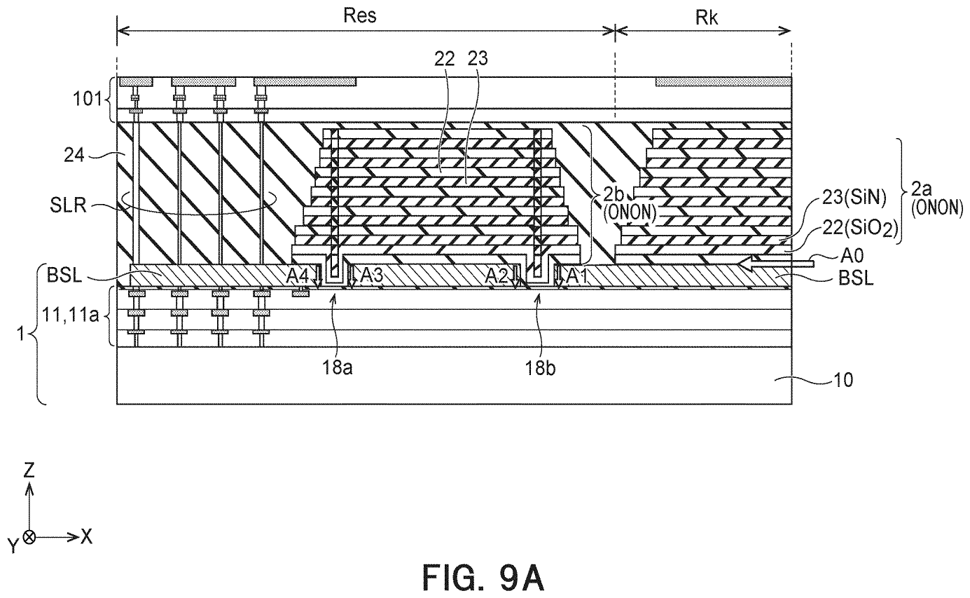

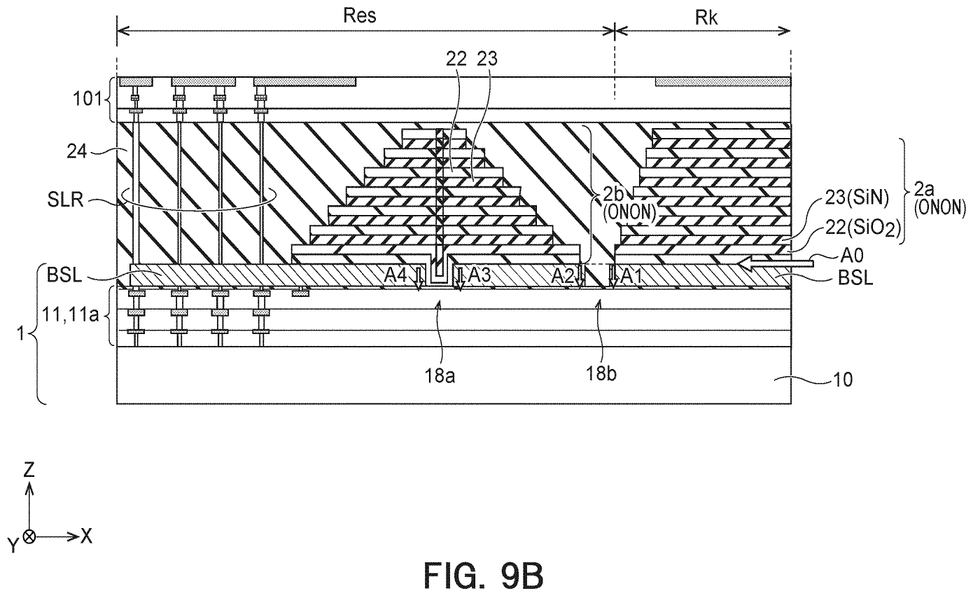

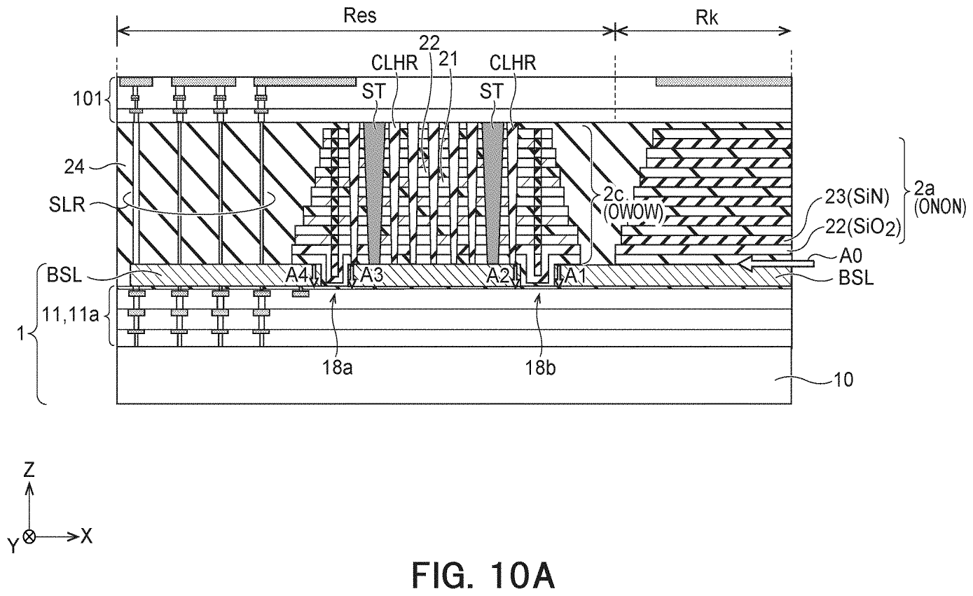

FIG. 9A is a sectional view illustrating a configuration example of a semiconductor device according to a second embodiment. In the second embodiment, a stacked body 2b is provided as a third stacked structure in the edge seal region Res and portions of the stacked body 2b are embedded in the slit parts 18a and 18b.

The stacked body 2b is provided above the slit parts 18a and 18b and has a stacked structure in which the insulating layers (for example, silicon oxide films) 22 and the sacrificial films (for example, silicon nitride films) 23 are alternately stacked. The stacked body 2b in which the insulating layers 22 and the sacrificial films 23 are alternately stacked is filled in the slit parts 18a and 18b. The stacked structure itself of the stacked body 2b can be same as that of the stacked body 2a. Therefore, the stacked body 2b can be formed in the same manner as that of the stacked body 2a. The staked body 2b is also provided along at least one portion of the outer edge of the stacked body 2 on the body part 19. For example, the stacked body 2b is provided only on a portion of the periphery part 17 facing a certain side of the periphery of the body part 19 in some cases. The stacked body 2b is sometimes provided discontinuously in the manner of islands on the periphery part 17. The stacked body 2b may be provided to correspond to the stacked body 2a at the periphery of the body part 19. Alternatively, the stacked body 2b may be continuously provided entirely around the periphery of the body part 19. In a case in which the slit parts 18a and 18b are provided in a region of the periphery part 17 where the stacked body 2b is not provided, an insulating film (for example, a silicon oxide film) is embedded in the slit parts 18a and 18b.

In the second embodiment, the material film (for example, a silicon oxide film) filled in the slit parts 18a and 18b is removed before the insulating layers 22 and the sacrificial films 23 are alternately deposited. That is, the inner portions of the slit parts 18a and 18b are voided. Accordingly, when the insulating layers 22 and the sacrificial films 23 are alternately deposited, the insulating layers 22 and the sacrificial films 23 are stacked also in the slit parts 18a and 18b and filled therein.

Misalignments of layers are produced in the stacked structure of the insulating layers 22 and the sacrificial films 23 provided above the slit parts 18a and 18b due to the filing of the stacked structure of the insulating layers 22 and the sacrificial films 23 in the inner portions of the slit parts 18a and 18b. However, these misalignments of layers do not affect the characteristics of the semiconductor storage device 100a. Other configurations of the second embodiment may be identical to corresponding ones of the first embodiment.

The second embodiment can achieve effects identical to those of the first embodiment. Furthermore, portions of the insulating layers 22 and the sacrificial films 23 are stacked in the horizontal direction and boundary portions between the insulating layer 22 and the sacrificial film 23 extend in the Z direction on inner side surfaces of the slit parts 18a and 18b. Therefore, film peeling can be guided to the −Z direction between the inner side surfaces of the slit parts 18a and 18b and the stacked body 2b and can be guided to the −Z direction also by the interfaces between the insulating layer 22 and the sacrificial film 23. Therefore, progression of film peeling toward the chip body region Rc can be further suppressed.

### (Modification)

FIG. 9B is a sectional view illustrating a configuration example of a semiconductor device according to a modification of the second embodiment. In the second embodiment described above, the stacked body 2b is filled in both the slit parts 18a and 18b. However, the stacked body 2b may be filled only in either the slit parts 18a or 18b as in the present modification. In this case, an insulating film (for example, a silicon oxide film) is embedded in the other slit parts 18a or 18b. Other configurations of the present modification may be identical to corresponding ones of the second embodiment. Therefore, the present modification can achieve effects identical to those of the second embodiment.

### Third Embodiment

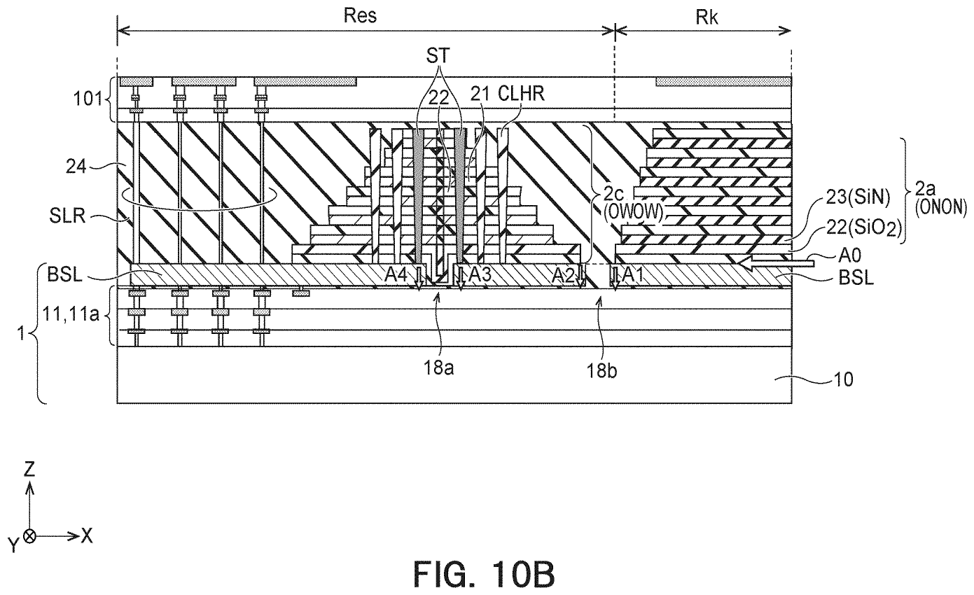

FIG. 10A is a sectional view illustrating a configuration example of a semiconductor device according to a third embodiment. In the third embodiment, a stacked body 2c is provided as a third stacked structure in the edge seal region Res and portions of the stacked body 2c are embedded in the slit parts 18a and 18b.

The stacked body 2c is provided above the slit parts 18a and 18b and has a stacked structure (OWOW) in which the insulating layers (for example, a silicon oxide film) 22 and the electrode films (for example, tungsten) 21 are alternately stacked. The stacked body 2c in which the insulating layers 22 and the electrode films 21 are alternately stacked is filled in the slit parts 18a and 18b. The stacked structure itself of the stacked body 2c can be the same as that of the stacked body 2 being the first stacked structure provided in the chip body region Rc. Therefore, the stacked body 2c can be formed in the same manner as that of the stacked body 2. The stacked body 2c is provided along at least one portion of the outer edge of the stacked body 2 on the body part 19. For example, the stacked body 2c is provided only on a portion of the periphery part 17 facing a certain side of the periphery of the body part 19 in some cases. The stacked body 2c is sometimes provided discontinuously in the manner of islands on the periphery part 17. The stacked body 2c may be provided to correspond to the stacked body 2a at the periphery of the body part 19. Alternatively, the stacked body 2c may be continuously provided entirely around the periphery of the body part 19. In a case in which the slit parts 18a and 18b are provided in a region of the periphery part 17 where the stacked body 2c is not provided, an insulating film (for example, a silicon oxide film) is embedded in the slit parts 18a and 18b.

Since the stacked body 2c is formed at the same time as the stacked body 2, the deep slits ST and the columnar parts CLHR are provided in the stacked body 2c. The deep slits ST are used at the time of replacement of the sacrificial films 23 with the electrode films 21, and the sacrificial films 23 are replaced with the electrode films 21 through the deep slits ST. In this replacing process, the columnar parts CLHR function as support members for holding voids formed when the sacrificial films 23 are removed from the stacked body 2c. For example, a conductive body (a metal material) being a second conductive film that is electrically insulated from the stacked body 2c by an insulator and that is electrically connected to the buried source layer BSL is filled in the deep slits ST similarly to the plate-like parts 3 in FIG. 1B. The deep slits ST in the stacked body 2c also have a same function as that of the crack stopper CST in FIG. 8, as well as being used in the replacing process, particularly when continuously provided entirely around the periphery of the body part 19 along with the stacked body 2c.

In the third embodiment, the material film (for example, a silicon oxide film) filled in the slit parts 18a and 18b is removed before the insulating layers 22 and the sacrificial films 23 are alternately deposited. That is, the inner portions of the slit parts 18a and 18b are voided. Accordingly, when the insulating films 22 and the sacrificial films 23 are alternately deposited, the insulating films 22 and the sacrificial films 23 are stacked also in the slit parts 18a and 18b and filled therein. The sacrificial films 23 are then replaced with the electrode films 21 in the replacing process, whereby the stacked body 2c in which the insulating layers 22 and the electrode films 21 are alternately stacked is filled in the slit parts 18a and 18b.

The filling of the stacked structure including the insulating layers 22 and the electrode films 21 in the inner portions of the slit parts 18a and 18b produces misalignments of layers in the stacked structure of the insulating layers 22 and the electrode films 21 above the slit parts 18a and 18b. However, these misalignments of layers do not affect the characteristics of the semiconductor storage device 100a. Other configurations of the third embodiment may be identical to corresponding ones of the first embodiment.

The third embodiment can achieve effects identical to those of the first embodiment. Furthermore, portions of the insulating layers 22 and the electrode films 21 are stacked in the horizontal direction and boundary portions between the insulating layer 22 and the electrode film 21 extend in the Z direction on the inner side surfaces of the slit parts 18a and 18b. Therefore, film peeling can be guided to the −Z direction between the inner side surfaces of the slit parts 18 and 18b and the stacked body 2c, and can be guided to the −Z direction also by the interfaces between the insulating layer 22 and the electrode film 21. Accordingly, progression of the film peeling toward the chip body region Rc can be further suppressed.

The stacked structure (OWOW) including the insulating layers (for example, silicon oxide films) 22 and the electrode films (for example, tungsten) 21 is expected to have a higher effect of suppressing progression of the film peeling than the stacked structure (ONON) including the insulating layers (silicon oxide films) 22 and the sacrificial films (silicon nitride films) 23 being the third insulating layers. This is because, for example, an interface between tungsten and a silicon dioxide film has higher adhesion than an interface between a silicon nitride film and a silicon oxide film. Therefore, use of the stacked structure (OWOW) including the insulting layers (for example, silicon oxide films) 22 and the electrode films (for example, tungsten) 21 as the stacked body 2c can suppress progression of film peeling more than in the second embodiment.

### (Modification)

FIG. 10B is a sectional view illustrating a configuration example of a semiconductor device according to a modification of the third embodiment. In the third embodiment described above, the stacked body 2c is filled in both the slit parts 18a and 18b. However, the stacked body 2c may be filled only in either the slit parts 18a or 18b as in the present modification. In this case, an insulating film (for example, a silicon oxide film) is filled in the other slit parts 18a or 18b. Other configurations of the present modification may be identical to corresponding ones of the third embodiment. Therefore, the present modification can achieve effects identical to those of the third embodiment.

### Fourth Embodiment

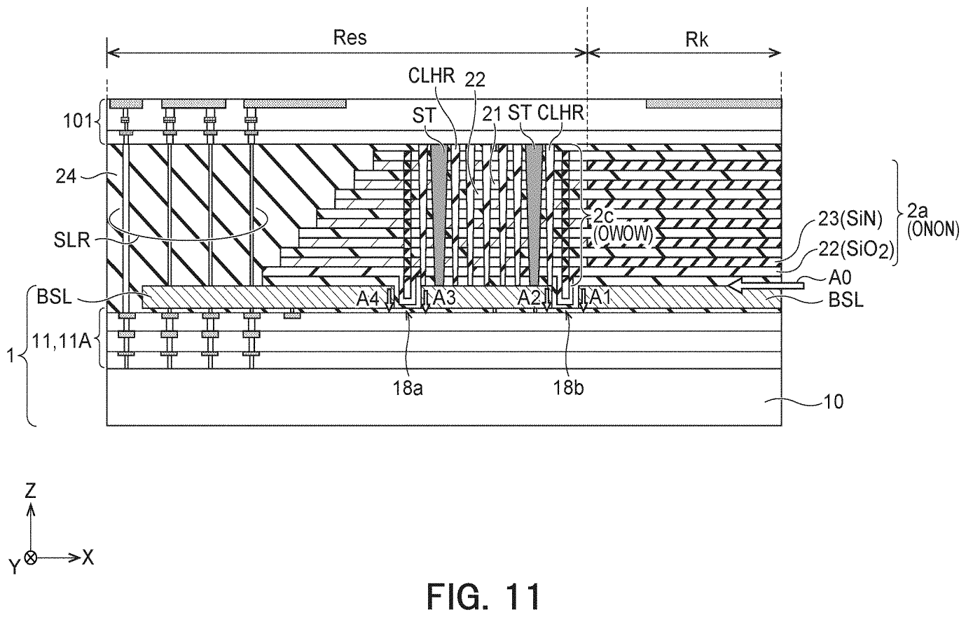

FIG. 11 is a sectional view illustrating a configuration example of a semiconductor device according to a fourth embodiment. In the fourth embodiment, the stacked body 2c in the edge seal region Res and the stacked body 2a in the kerf region Rk are connected. In this case, the deep slits ST are formed in the edge seal region Res and are not formed in the kerf region Rk. Accordingly, after the stacked body 2a is formed in the edge seal region Res and the kerf region Rk, the sacrificial films 23 in the edge seal region Res are replaced with the material of the electrode films 21 through the deep slits ST in the replacing process. Meanwhile, the sacrificial films 23 in the kerf region Rk remain as they are without being replaced. In this way, even when the stacked body 2c in the edge seal region Res and the stacked body 2a in the kerf region Rk are connected, the sacrificial films 23 can be replaced with the electrode films 21 only in the stacked body 2c in the edge seal region Res.

In this case, the slit parts 18a and 18b are filled with the stacked body 2c including the insulating layers 22 and the electrode films 21. Other configurations of the fourth embodiment may be identical to corresponding ones of the third embodiment. Therefore, the fourth embodiment can achieve effects identical to those of the third embodiment.

In the fourth embodiment, the stacked body 2a and the stacked body 2c are continuous as one stacked body. Therefore, for example, if the stacked body (for example, ONON) 2a is lost at the end portion 1e in FIG. 4 at the time of dicing, the stacked body (for example, OWOW) 2c appears at the outer edge of a singulated semiconductor chip. In this case, only the stacked body 2c is formed as the second stacked structure along at least one portion of the outer edge of the stacked body 2 (the first stacked structure) on the body part 19, and the slit parts 18a and 18b are arranged under the stacked body 2c as the second stacked structure. The stacked body 2c itself being the second stacked structure is embedded in the slit parts 18a and 18b.

In the fourth embodiment, the deep slits ST extending in the stacked body 2c in the stacking direction (the Z direction) are provided. The deep slits ST are configured to be filled with a conductive body (a second conductive film) electrically insulated from the stacked body 2c by an insulator on inner walls of the deep slits ST similarly to the plate-like parts 3 in FIG. 1B as described above and extend in the Y direction in the stacked body 2c in a planar view seen from the Z direction. It suffices that the deep slits ST are provided in the stacked body 2c where the replacing process is performed in the periphery part 17, and the deep slits ST do not need to be provided in a region of the periphery part 17 where the stacked body 2c is not arranged.

### Fifth Embodiment

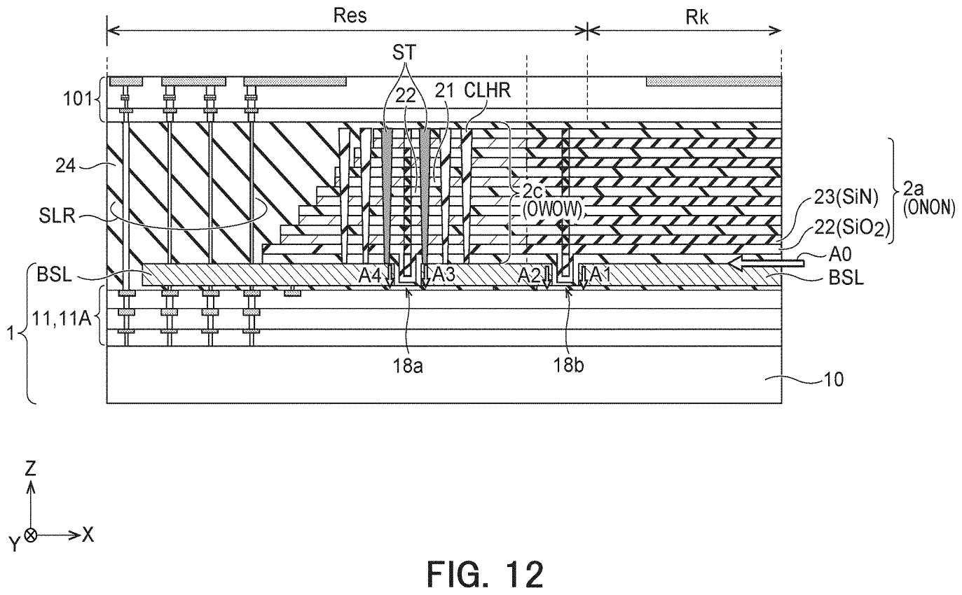

FIG. 12 is a sectional view illustrating a configuration example of a semiconductor device according to a fifth embodiment. The fifth embodiment is the same as the fourth embodiment in that the stacked body 2c in the edge seal region Res and the stacked body 2a in the kerf region Rk are connected. Meanwhile, the stacked body (for example, OWOW) 2c is not provided into the slit parts 18b and the stacked body 2a (for example, ONON) is provided into the slit parts 18b in the fifth embodiment. In this case, the deep slits ST are formed near the slit parts 18a in the edge seal region Res and are not formed near the slit parts 18b and in the kerf region Rk. Accordingly, after the stacked body 2a is formed in the edge seal region Res and the kerf region Rk, the sacrificial films 23 near the slit parts 18a in the edge seal region Res are replaced with the material of the electrode films 21 through the deep slits ST in the replacing process. Meanwhile, the sacrificial films 23 near the slit parts 18b and in the kerf region Rk remain as they are without being replaced. Accordingly, the slit parts 18a are filled with the stacked body (for example, OWOW) 2c including the insulating layers 22 and the electrode films 21 and the slit parts 18b are filled with the stacked body (for example, ONON) 2a including the insulating layers 22 and the sacrificial films 23. Other configurations of the fifth embodiment may be identical to corresponding ones of the third embodiment. Therefore, the fifth embodiment can achieve effects identical to those of the third embodiment.

As described above, the stacked bodies 2a and 2c may be connected to each other. In this case, the boundary between the stacked bodies 2a and 2c can be controlled according to the positions of the deep slits ST.

Also in the fifth embodiment, similarly to the fourth embodiment, the stacked body 2a and the stacked body 2c are continuous as one stacked body. Further, also similarly to the fourth embodiment, the deep slits ST are provided in the stacked body 2c.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
a first insulating layer provided on the semiconductor substrate;
a first conductive film provided on the first insulating layer;
a first stacked structure provided on the first conductive film, the first stacked structure including a plurality of first electrode films and a plurality of second insulating layers alternately stacked;
a semiconductor member extending in the first stacked structure in a staking direction of the first electrode films;
a charge accumulating member provided between one of the first electrode films and the semiconductor member;
a conductive member provided along an outer edge of the first stacked structure around the first stacked structure and electrically connected to the semiconductor substrate; and
a second stacked structure provided at least partially around the conductive member, the second stacked structure including the second insulating layers and a plurality of third insulating layers alternately stacked on the first conductive film, wherein
the first conductive film comprises
a body part arranged below the first stacked structure,
a periphery part provided at a periphery of the body part away from the body part, and
a slit part provided in the first conductive film between the conductive member and the second stacked structure in the periphery part.

2. The device of claim 1, wherein
the slit part includes a plurality of first slits and a plurality of second slits spaced from each other, and
the first and second slits are arranged alternately in a staggered manner in the periphery part as viewed from the stacking direction.

3. The device of claim 2, wherein the first and second slits are spaced from each other as viewed from the stacking direction, and end portions of the first and second slits overlap with each other as viewed from a first direction from the body part to the periphery part.

4. The device of claim 1, further comprising a third stacked structure provided between the conductive member and the second stacked structure in the periphery part, the third stacked structure including the first electrode films and the second insulating layers or the second insulating layers and the third insulating layers alternately stacked on the first conductive film, wherein
the third stacked structure is provided in at least a portion of the slit part.

5. The device of claim 4, further comprising a second conductive film extending in the third stacked structure in the stacking direction.

6. The device of claim 1, wherein the body part of the first conductive film is a source layer electrically connected to the semiconductor member.

7. A semiconductor device comprising:
a semiconductor substrate;
a first insulating layer provided on the semiconductor substrate;
a first conductive film provided on the first insulating layer;
a first stacked structure provided on the first conductive film, the first stacked structure including a plurality of first electrode films and a plurality of second insulating layers alternately stacked;
a semiconductor member extending in the first stacked structure in a stacking direction of the first electrode films;
a charge accumulating member provided between one of the first electrode films and the semiconductor member;
a conductive member provided along an outer edge of the first stacked structure around the first stacked structure and electrically connected to the semiconductor substrate; and
a second stacked structure provided at least partially around the conductive member, the second stacked structure including the first electrode films and the second insulating layers or the second insulating layers and a plurality of third insulating layers alternately stacked on the first conductive film, wherein
the first conductive film comprises
a body part arranged below the first stacked structure,
a periphery part provided at a periphery of the body part away from the body part, and
a slit part provided in the first conductive film positioned below the second stacked structure on the periphery part, and wherein
the second stacked structure is provided in the slit part, and
at least a portion of the second stacked structure is a stacked structure including the first electrode films and the second insulating layers.

8. The device of claim 7, wherein
the slit part includes a plurality of first slits and a plurality of second slits spaced from each other, and
the first and second slits are arranged alternately in a staggered manner in the periphery part as viewed from the stacking direction.

9. The device of claim 8, wherein the first and second slits are spaced from each other as viewed from the stacking direction, and end portions of the first and second slits overlap with each other as viewed from a first direction from the body part to the periphery part.

10. The device of claim 7, further comprising a second conductive film extending in the second stacked structure in the stacking direction.

11. The device of claim 8, wherein the second stacked structure including the first electrode films and the second insulating layers alternately stacked is provided in the first and second slits.

12. The device of claim 8, wherein
the second stacked structure including the first electrode films and the second insulating layers alternately stacked is provided in the first slits, and
another structure is provided in the second slits.

13. The device of claim 7, wherein the body part of the first conductive film is a source layer electrically connected to the semiconductor member.

14. A semiconductor device comprising:
a semiconductor substrate;
a first insulating layer provided on the semiconductor substrate;
a first conductive film provided on the first insulating layer;
a first stacked structure provided on the first conductive film, the first stacked structure including a plurality of first electrode films and a plurality of second insulating layers alternately stacked;
a semiconductor member extending in the first stacked structure in a staking direction of the first electrode films;
a charge accumulating member provided between one of the first electrode films and the semiconductor member;
a conductive member provided along an outer edge of the first stacked structure around the first stacked structure and electrically connected to the semiconductor substrate;
a second stacked structure provided at least partially around the conductive member, the second stacked structure including the first electrode films and the second insulating layers or the second insulating layers and a plurality of third insulating layers alternately stacked on the first conductive film; and
a second conductive film extending in the second stacked structure in the stacking direction, wherein
the first conductive film comprises
a body part arranged below the first stacked structure,
a periphery part provided at a periphery of the body part away from the body part, and
a slit part provided in the first conductive film positioned below the second stacked structure on the periphery part.

15. The device of claim 14, wherein
the slit part includes a plurality of first slits and a plurality of second slits spaced from each other, and
the first and second slits are arranged alternately in a staggered manner in the periphery part as viewed from the stacking direction.

16. The device of claim 15, wherein the first and second slits are spaced from each other as viewed from the stacking direction, and end portions of the first and second slits overlap with each other as viewed from a first direction from the body part to the periphery part.

17. The device of claim 14, wherein the second stacked structure is provided in the slit part.

18. The device of claim 15, wherein the second stacked structure including the first electrode films and the second insulating layers alternately stacked is provided in the first and second slits.

19. The device of claim 15, wherein
the second stacked structure including the first electrode films and the second insulating layers alternately stacked is provided in the first slits, and
another structure is provided in the second slits.

20. The device of claim 14, wherein the body part of the first conductive film is a source layer electrically connected to the semiconductor member.
